(19) United States
(12) Patent Application Publication
(10) Pub. No.: US 2009/0309670 A1
(43) Pub. Date: Dec. 17, 2009

(54) Switched Bands Phase Shifter

(76) Inventors: Tsufit Magrisso, Karmiel (IL); Sharon Matrasso, Misgav (IL); David Kryger, Karmiel (IL)

Correspondence Address: YORAM TSIVION, P.O. BOX 1307, PARDES HANNA, 37111, IL

(21) Appl. No.: 12/440,930

(22) PCT Filed: Sep. 11, 2007
(86) PCT No.: PCT/IL07/01117

§ 371 Date: Mar. 12, 2009

(30) Foreign Application Priority Data
Sep. 12, 2006 (IL) 178021

(51) Int. Cl. H03C 7/04

(52) U.S. Cl. 332/144

(57) ABSTRACT

A multiband phase shifter (MBPS) consists of at least two band phase shifters (BPSs). Each BPS has characteristic operating bandwidth such that the respective central frequency of the operating bandwidth of any such BPS is different than the other central frequencies of the other operating bandwidth associated with other BPS respectively. The MBPS input signal can be switched to any of the BPS while a switch controller controls the switching.

The present application claims the benefit of priority to IL Patent Application Serial Number 178021, filed Sep. 12, 2006, entitled “switched bands phase shifter” The aforementioned application is incorporated herein by reference.

### FIELD OF THE INVENTION

The present invention is in the field of microwave devices. More specifically the invention relates to phase shifters.

### BACKGROUND OF THE INVENTION

A phase shifter is a two-port network with the provision that the phase difference between output and input signals can be controlled using a control signal, usually a dc bias. Phase shifters with low insertion loss, low drive power, low phase error and low production cost are the key to the development of lightweight phased array antennas. Microwave and millimeter wave phased array antennas are useful because of their ability to steer wave beams in space without physically moving the antenna elements. A typical phased array antenna may have several thousand elements in its array fed by a phase shifter for every antenna element.

Phase shifters are generally classified in either of two categories, digital and analogue. In a digital phase shifter, the phase can be shifted between a few predetermined discrete values such as 90°, 45°, 22.5°, 11.25° etc. Usually the changes of those phases at the phase shifter output are controlled by a controller with a parallel input which will be further explained below. Such phase shifters refers to hereinafter as digital phase shifters (DPS). In analogue phase shifters, a continuous variation of phase is possible.

Digital phase shifters provide a discrete set of phase states that are controlled by two-state “phase bits.” An example of prior art digital phase shifter is described schematically in FIG. 1 to which reference is now made. Digital phase shifter (DPS) 20 receives a signal in input 22, the signal is then fed to N bit phase shifter 24 (N is an integer referred to as the order of the phase shifter, typically having a value of 2, 3, 4, 5 and 6). The number of phase shifter discrete steps, L, is define as L=2^{N} thus 360° is divided by L is to L equal discrete steps. For example a 2 bit phase shifter, N=2 , L=4 is a phase shifter with 4 90° discrete steps. A six bit phase shifter would have 64 discrete steps of 5.625° each. The digital controller 26 determines, for each phase shifter bit, whether it is “on” or “off” state. The phase shift of the signal at output 28 with respect to input 22 is tuned by the digital input command 30 to the digital controller. The convention for digital phase shifters is that no phase shift of the input signal is the reference or “off” state, and a specific phase shift of the input signal is the “on” state. Thus a 90° phase shifter actually provides −90° of phase shift in its “on” state. The reflection-type phase shifter (RTPS) is a simple phase shifter design that can be realized in many different forms which include a quadrature or Lange coupler and two identical reflective loads, as to be further described. Lange coupler is a four port, passive RF component, widely used in power combiners and non linear elements such as mixers and modulators. The coupling is derived from closely spaced transmission lines, such as microstrip lines. Reflective load is a one-port circuit that changes the phase of the reflected signal in respect to the phase of the incident signal. The quadrature coupler's function is to enable phase shifting in a wide band, using its wide band quadrature quality to create reflection topology. The reflective load responsible for the phase shift can be realized in many different ways. The technique most appropriate depends on the technology used to implement the phase shifter. Variables such as size and signal loss (attenuation) must also be taken into account when deciding on a reflective load topology. In order to obtain the expected behavior, two reflection loads must be included in the RIPS in which both are connected to the Lange couplers direct and coupled ports. The RTPS's output signal is received at the quadrature hybrid coupler's isolated port, and will ideally be isolated from the RTPS input signal. An example of prior art RTPS is described schematically in FIG. 2A to which reference is now made. Coupler 40 divides input signal from port 42 into two ports 46, 48 which are connected to reflection loads 50, 52. An RTPS of the prior art illustrating the signal phase shift between RTPS input and output is described schematically in FIG. 2B to which reference is now made. Input port 42 of coupler 40 receives an input signal, and is therefore considered a signal with a 0° phase. The coupler divides the input signal into two ports. Port 46 which referred to as coupled port and port 48 which referred to as direct port. The input signal power is divided between those ports. Port 46 receives portion of the input signal power with no phase shift in respect to the input signal phase. Port 48 receives the other portion of the input signal power with −90° phase shift in respect to the input signal phase. The reflective loads (RL's) 50, 52 reflect those signals back to ports 42, 54 such that the reflected signals from RL 50 are reflected to port 42 with phase shift −φ and reflected also to port 54 (which referred to as isolated port) with phase shift of −90°−φ° in respect to input signal phase. The reflected signals from RL 52 are reflected to port 42 with a phase shift of −φ−180° and reflected also to port 54 with phase shift of −90°−φ20 with respect to input signal phase. The reflected signals that propagate to port 42 cancel each other and thus signal is not reflected back to port 42. The reflected signals that propagate to port 54 recombined such that the phase of output signal in port 54 is shifted by −90°−φ° with respect to the input signal phase. Progress in GaAs material processing and device development has led to the feasibility of the monolithic microwave integrated circuit (MMIC), in which all passive and active components required for a given circuit can be grown or implemented on the substrate. To reduce chip area and insertion loss (IL) of MMIC reflective type digital phase shifter, a circuit topology is implemented in which more than one bit share a single Lange coupler, as disclosed in “A multi octave five-bit MMIC phase shifter with compatible different control signals” by Dai Yongsheng, Chen Xiaojian, Chen Tangsheng, Yu Tufa, Liu Lin, Lin Jinting, in: 2^{nd} International conference on microwave and millimeter wave technology proceedings, pp 142-145, 2000, the contents of which are incorporated herein by reference.

### BRIEF DESCRIPTION OF THE DRAWINGS

FIG. 1 is a schematic description of prior art typical digital phase shifter;

FIG. 2A is a schematic description of prior art RTPS;

FIG. 2B is schematic description of prior art RTPS example illustrating the signal phase shift between RTPS input and output;

FIG. 3 is a schematic description of an exemplary digital multiband phase shifter in accordance with the present invention;

FIG. 4 is a graph illustrating the multiband phase shifter (MBPS) phase error versus frequency;

FIG. 5 is a layout of a MBPS illustrated schematically in accordance with a preferred embodiment of the present invention;

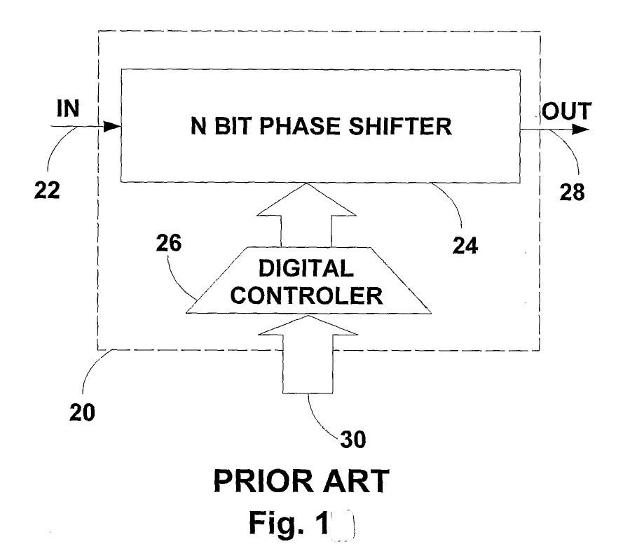

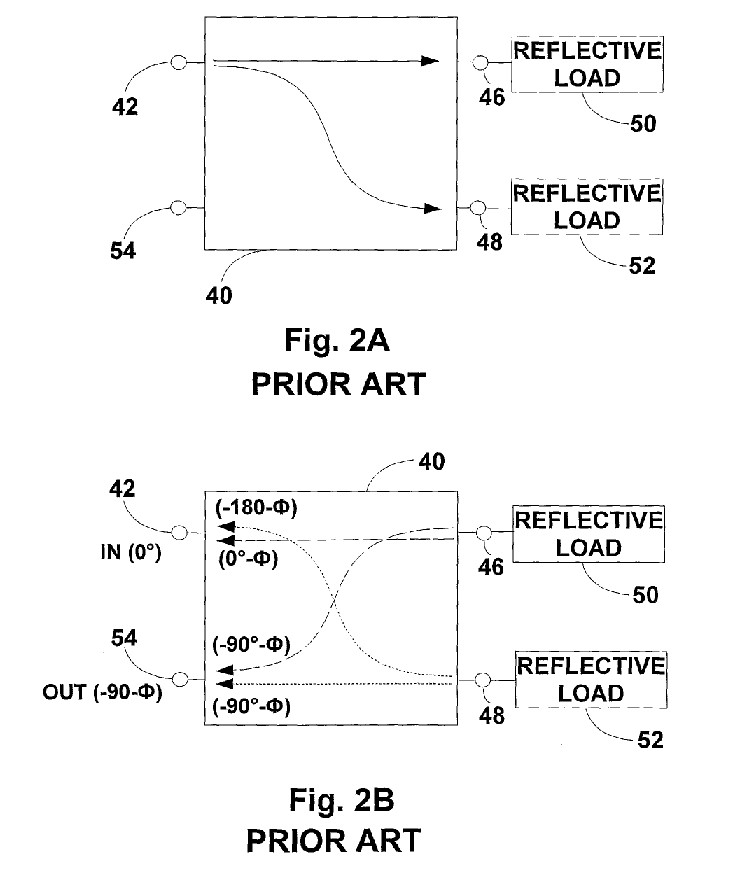

### DETAILED DESCRIPTION OF THE PRESENT INVENTION

In accordance with the present invention, a multiband phase shifter (MBPS) consists of at least two band phase shifters (BPSs). The MBPS input s signal can be switched to any of the BPS. Several types of band phase shifters are applicable in the context of the MBPS of the invention. For example switched delay line, rat-race, high/low pass, loaded-line, reflective BPSs.

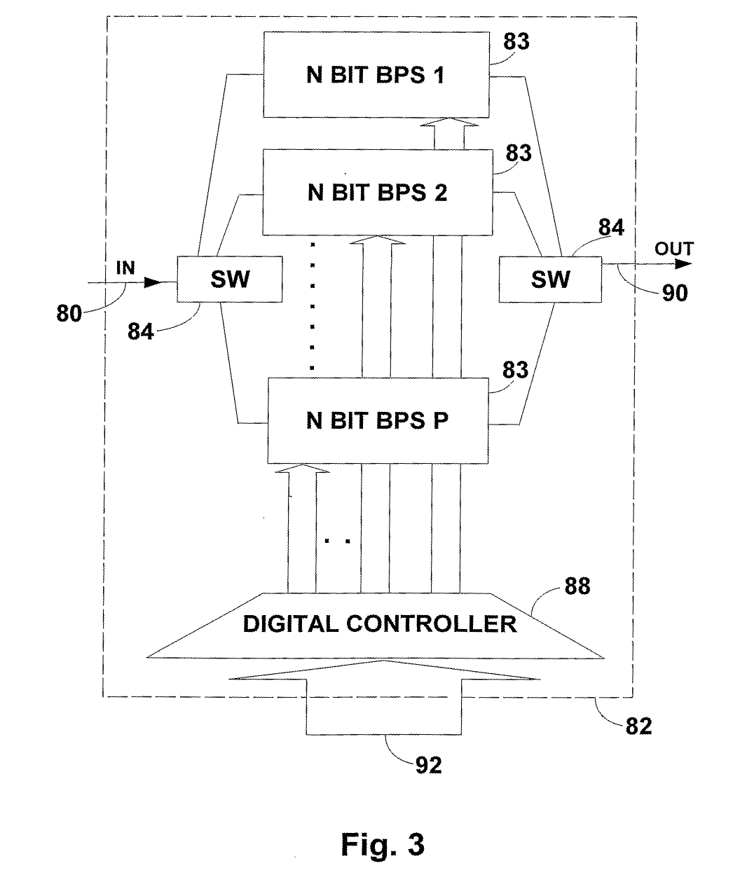

An example of a MBPS in accordance with the present invention is described schematically in FIG. 3 to which reference is now made. A signal 80 received in digital MBPS 82, is then fed to the input port of one of the band phase shifters (BPSs) 83. Selector switches 84 facilitate selecting a specific BPS out of the multiplicity of BPSs available. In some embodiments, a switch controller, not shown, is used to control switches 84. Digital controller 88 determines whether any specific phase shifter bit is in an “on” or “off” state. The phase shift of the signal at the digital MBPS output 90 is tuned by digital input command 92 received by the digital controller 88.

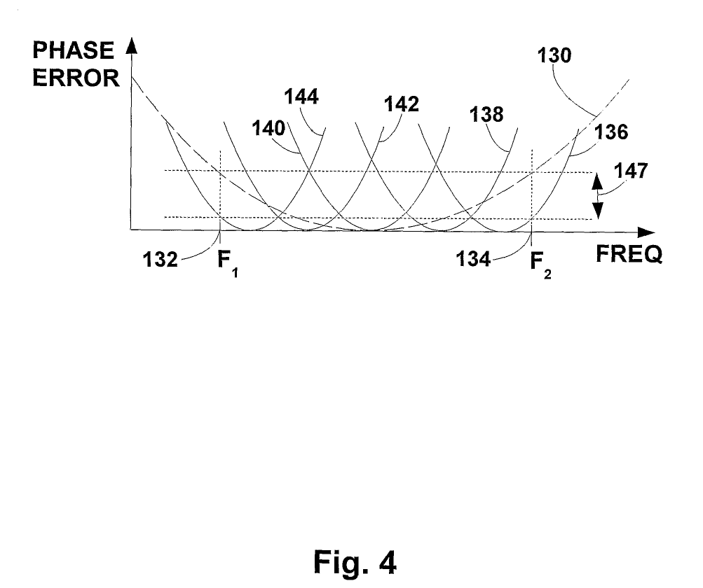

In a second aspect of the invention, the BPS's operating bandwidths can overlap as described below. A graph illustrating a typical phase error of BPSs with overlapping operating bandwidths is described schematically in FIG. 4 to which reference is now made. A phase error in the context of the present invention is defined as the root mean square (RMS) phase deviation from the desirable phase portion of the frequency response (referred to hereinafter as phase response) of all states, in all phase states of the MBPS phase response. The dashed line 130 designates an exemplary typical prior art graph of broad band phase shifter (BBPS) phase error versus frequency. The BBPS operates between F₁ 132 and F₂ 134 which are the nominal lower and upper frequency limits, respectively. In this example, the MBPS in accordance with the present invention consists of four BPS's, the convex graphs 136,138,140,142,144 designate the phase error as a function of frequency for BPS₁, BPS₂, BPS₃, BPS₄, BPS₅ respectively. Typically in reflective topology, each BPS uses one hybrid coupler such as Lange coupler for each bit. When two lower bit share a single Lange coupler as disclosed in the reference sited above, each BPS could uses one hybrid coupler for more than one bit.

The operating bandwidth of each BPS's is described by equation 1

BWₙ=F_{H}−F_{L} (1)

where n is an integer number having a values of 1,2,3,4,5. F_{H} and F_{L} are the highest and lowest frequencies respectively.

The frequency F_{c} of each BPS is described by equation 2

$${F}_{C} = \frac{{F}_{H} - {F}_{L}}{2} , \qquad ( 2 )$$

frequency F_{c} typically referred to as “central frequency”.

Each BPS's has a characteristic operating bandwidth, such that the respective central frequency of the operating bandwidth associated with any such BPS is different than the other central frequencies. One of the benefits of the use of the present invention is the overall decrease in phase error. As can be seen for example in FIG. 4, the phase error of the five BPS's 136,138,140,142,144 is smaller than the phase error MBPS 130. A particular phase error improvement as indicated by double headed arrow 147 at both the lower and the upper operational MBPS frequency limits.

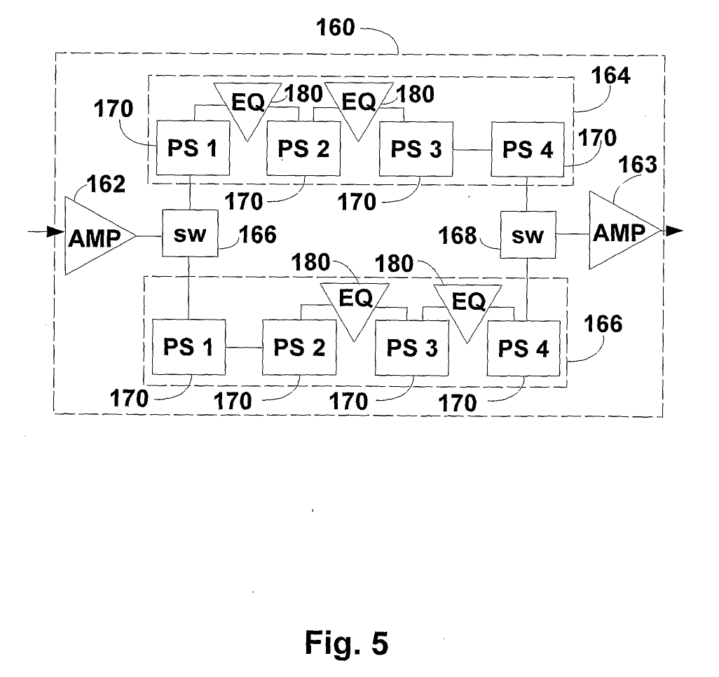

A schematic layout of a MBPS in accordance with a preferred embodiment of the present invention is illustrated schematically in FIG. 5 to which reference is now made. A signal is fed to MBPS 160, to be amplified by amplifier 162. The amplified signal is then fed either to BPS 164 or BPS 166. In the context of the present invention the amplifiers 162,163 are used to compensate for signal attenuation caused mainly by phase shifter insertion loss (IL) which is the ratio of the signal power launched at the input port of the phase shifter to the signal power at the output port. Switch controller, not shown, controls selector switches 166,168 to select either BPS 164 or 166. In this example each bit of the BPS is a reflective type phase shifter 170 referred to hereinafter as RL-type phase shifter. Active or passive equalizers 180 are placed between those phase shifters 170. Alternatively, the equalizers can be connected between other components or junctions of the MBPS not shown in the drawing. In the context of the present invention the equalizers are used to modify signal output amplitude so that the amplitude ripples of MBPS output signals are small i.e. MBPS signal output power is the same for all frequencies of MBPS operational bandwidth.

1. A system for accepting an input signal, and for providing a phase shifted output signal, said system comprising:
at least two band phase shifters (BPSs) having each a characteristic operating bandwidth, such that the respective central frequency of the operating bandwidth of any such BPS is different than the other central frequencies of the other operating bandwidth associated with other BPS respectively;
at least one selector switch to select a BPS to receive said input signal, and
a switch controller to control said switches.

2. A system as in claim 1, wherein said at least two BPSs are digital.

3. A system as in claim 2, wherein said at least two BPSs are reflective-type BPS.

4. A system as in claim 1, wherein said system employ at least one amplifier to compensate for signal attenuation caused mainly by coupler insertion loss (IL).

5. A system as in claim 1, further employing at least one equalizer to modify the signal output amplitude so that said output signal power is the same for all frequencies of the operational bandwidth of said system.

6. A system as in claim 3, wherein each of said at least two reflective-type BPS employ at least one hybrid coupler.

7. A system as in claim 1, wherein the operating bandwidth of at least two adjacent curves partial overlap.
